(19) United States
(12) Patent Application Publication
(10) Pub. No.: US 2009/0258162 A1
(43) Pub. Date: Oct. 15, 2009

(54) PLASMA PROCESSING APPARATUS AND METHOD

(75) Inventors: GAKU FURUTA, Sunnyvale, CA (US); Young-Jin Choi, Santa Clara, CA (US); Soo Young Choi, Fremont, CA (US); Beom Soo Park, San Jose, CA (US); John M. White, Hayward, CA (US); Suhail Anwar, San Jose, CA (US); Robin L. Tiner, Santa Cruz, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/422,183

(22) Filed: Apr. 10, 2009

Related U.S. Application Data
(63) Continuation-in-part of application No. 12/271,616, filed on Nov. 14, 2008.
(60) Provisional application No. 61/044,481, filed on Apr. 12, 2008.
(60) Provisional application No. 61/139,384, filed on Dec. 19, 2008.

(51) Int. Cl. C23C 16/44; C23C 16/00; H05H 1/24

(52) U.S. Cl. 427/569; 118/723 R; 118/723 IR

(57) ABSTRACT

The present invention generally includes a plasma enhanced chemical vapor deposition (PECVD) processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

### CROSS-REFERENCE TO RELATED APPLICATIONS

This application is a continuation-in-part of U.S. patent application Ser. No. 12/271,616 (APPM/13370), filed Nov. 14, 2008, which is herein incorporated by reference, which application claims priority to U.S. Provisional Patent Application Ser. No. 61/044,481 (APPM/013370L), filed Apr. 12, 2008, both of which are herein incorporated by reference. This application also claims priority to U.S. Provisional Patent Application Ser. No. 61/139,384 (APPM/13370L02) filed Dec. 19, 2008 and U.S. Provisional Patent Application Ser. No. 61/044,481 (APPM/013370L), filed Apr. 12, 2008, both of which are herein incorporated by reference.

### BACKGROUND OF THE INVENTION

1. Field of the Invention

Embodiments of the present invention generally relate to a processing chamber having the power supply coupled to the processing chamber at a location separate from the gas supply.

2. Description of the Related Art

As demand for larger flat panel displays and solar panels continues to increase, so must the size of the substrate and hence, the processing chamber. As the processing chamber size increases, higher RF current is sometimes necessary in order to offset dissipation of the RF current that occurs as the RF current travels away from the RF source. One method for depositing material onto a substrate for flat panel displays or solar panels is plasma enhanced chemical vapor deposition (PECVD). In PECVD, process gases may be introduced into the process chamber through a showerhead and ignited into a plasma by an RF current applied to the showerhead. As substrate sizes increase, the RF current applied to the showerhead may also correspondingly increase. With the increase in RF current, the possibility of premature gas breakdown prior to the gas passing through the showerhead increases as does the possibility of parasitic plasma formation above the showerhead.

Therefore, there is a need in the art for an apparatus that permits the delivery of sufficient RF current while reducing parasitic plasma formation.

### SUMMARY OF THE INVENTION

The present invention generally includes a PECVD processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

In one embodiment, a plasma processing apparatus is disclosed. The apparatus includes a processing chamber having a gas distribution plate and a generally rectangularly shaped backing plate, one or more power sources coupled to the backing plate at one or more first location and one or more gas sources coupled to the backing plate at three other locations that are each separate from the one or more first locations. A first of the three locations is disposed a substantially equal distance between two parallel sides of the backing plate.

In another embodiment, a plasma enhanced chemical vapor deposition apparatus is disclosed. The apparatus includes a processing chamber having a slit valve opening through at least one wall and a gas distribution showerhead disposed within the processing chamber and spaced from a substrate support. The apparatus also may include a backing plate disposed behind the gas distribution showerhead and spaced therefrom. The backing plate may have three openings therethrough at three locations. A first location of the three locations may be disposed farther from the slit valve opening than the other two locations. The apparatus may also include one or more gas sources coupled to the backing plate at the three locations and an RF power source coupled to the backing plate at a location spaced from the three locations.

In another embodiment, a method is disclosed. The method includes introducing processing gas into a chamber through a first location, igniting the processing gas into a plasma and depositing material onto a substrate. The method may also include introducing cleaning gas into one or more remote plasma source igniting the cleaning gas into a plasma in the one or more remote plasma sources and flowing radicals from the remotely ignited cleaning gas plasma into the chamber through the first location and at least one other location separate from the first location.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic representation of a power source 102 and a gas source 104 coupled to a processing chamber 100 according to one embodiment of the invention.

FIG. 2A is a schematic cross-sectional view of a processing chamber 200 according to one embodiment of the invention.

FIG. 2B is a schematic cross-sectional view of the processing chamber 200 of FIG. 2A showing the RF current path.

FIG. 3 is a schematic isometric view of a backing plate 302 of a processing chamber 300 according to one embodiment of the invention.

FIG. 4 is a schematic illustration of a coupling between a remote plasma source and the processing chamber according to one embodiment of the invention.

FIG. 5 is a schematic isometric view of a backing plate 502 of a processing chamber 500 according to one embodiment.

FIG. 6 is a schematic top view of a substrate support showing locations of corresponding gas introduction passages according to one embodiment.

FIG. 7 is a schematic top view of an apparatus 700 according to another embodiment.

FIG. 8 is a schematic top view of an apparatus 800 according to another embodiment.

FIG. 9 is a schematic top view of an apparatus 900 according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally includes a PECVD processing chamber having an RF power source coupled to the backing plate at a location separate from the gas source. By feeding the gas into the processing chamber at a location separate from the RF power, parasitic plasma formation in the gas tubes leading to the processing chamber may be reduced. The gas may be fed to the chamber at a plurality of locations. At each location, the gas may be fed to the processing chamber from the gas source by passing through a remote plasma source as well as an RF choke or RF resistor.

The invention is illustratively described below in reference to a chemical vapor deposition system, processing large area substrates, such as a PECVD system, available from AKT America, Inc., a division of Applied Materials, Inc., Santa Clara, Calif. However, it should be understood that the apparatus and method may have utility in other system configurations, including those systems configured to process round substrates.

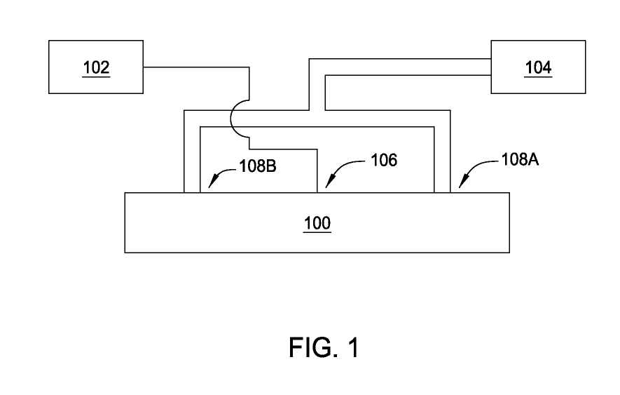

FIG. 1 is a schematic representation of a power source 102 and a gas source 104 coupled to a processing chamber 100 according to one embodiment of the invention. As shown in FIG. 1, the power source 102 is coupled to the processing chamber 100 at a location 106 that is different from the locations 108A, 108B where the gas source 104 is coupled to the processing chamber 100.

It is to be understood that while two locations 108A, 108B have been shown for coupling the gas source 104 to the processing chamber 100, the number of locations 108A, 108B is not to be limited to two. A single location 108A, 108B may be utilized. Alternatively, more than two locations 108A, 108B may be used. When a plurality of locations 108A, 108B are used to couple the gas source 104 to the processing chamber 100, the gas may flow to the processing chamber 100 to the plurality of locations 108A, 108B from a common gas source 104. In one embodiment, each location 108A, 108B where gas flows to the processing chamber 100 may have its own dedicated gas source 104.

It is also to be understood that while a single location 106 is shown for coupling the power source 102 to the processing chamber 100, the power source 102 may be coupled to the processing chamber 100 at a plurality of locations 106. In one embodiment, the power source 102 may comprise an RF power source. Additionally, while the power source 102 is shown to be coupled to the processing chamber 100 at a location 106 that corresponds to the substantial center of the processing chamber 100, the power source 102 may be coupled to the processing chamber 100 at a location 106 that does not correspond to the substantial center of the processing chamber 100.

While the gas source 104 is shown to be coupled to the processing chamber 100 at locations 108A, 108B that are disposed substantially away from the center of the processing chamber 108A, 108B, the locations 108A, 108B are not so limited. The locations 108A, 108B may be located closer to the center of the processing chamber 100 than the location 106 where the power source 102 is coupled to the processing chamber 100.

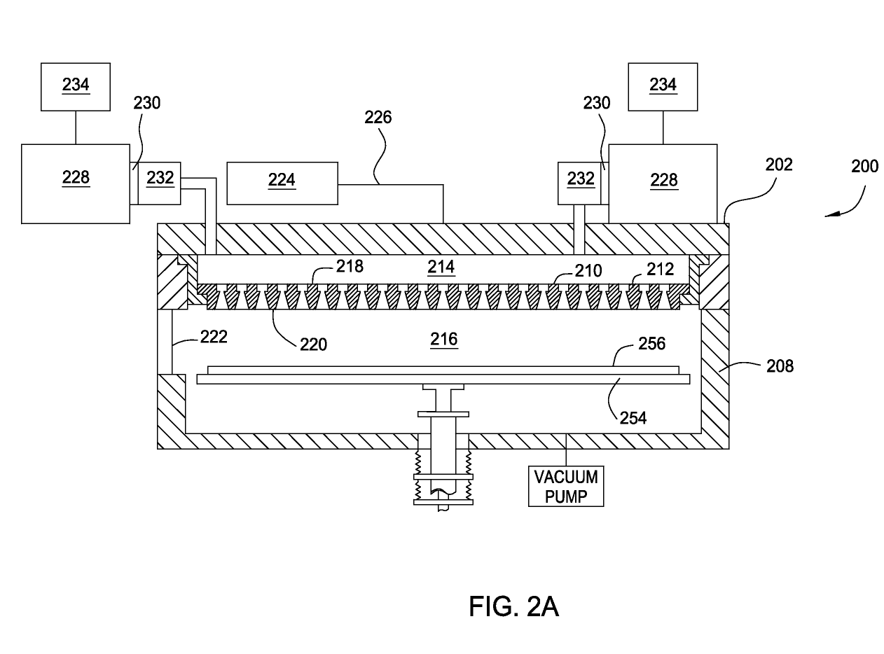

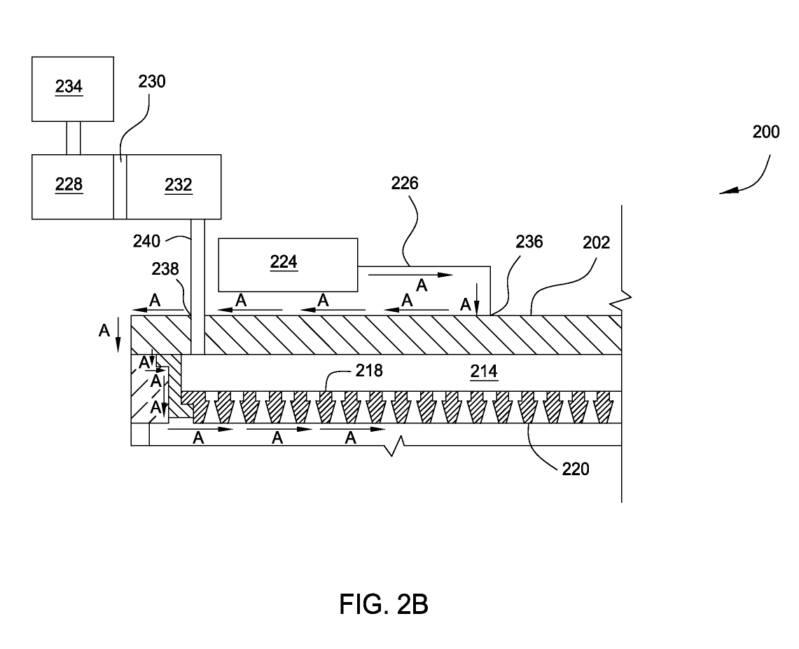

FIG. 2A is a schematic cross-sectional view of a processing chamber 200 according to one embodiment of the invention. The processing chamber 200 is a PECVD chamber. The processing chamber 200 has a chamber body 208. Within the chamber body, a susceptor 204 may be disposed to sit opposite a gas distribution showerhead 210. A substrate 206 may be disposed on the susceptor 204. The substrate 206 may enter the processing chamber 200 through a slit valve opening 222. The substrate 206 may be raised and lowered by the susceptor 204 for processing, removal and/or insertion of the substrate 206.

The showerhead 210 may have a plurality of gas passages 212 passing through the showerhead 210 from an upstream side 218 to a downstream side 220. The downstream side 220 of the showerhead 210 is the side of the showerhead that faces the substrate 206 during processing.

The showerhead 210 is disposed in the processing chamber 200 across a processing space 216 from the substrate 206. Behind the showerhead 210, a plenum 214 is present. The plenum 214 is between the showerhead 210 and the backing plate 202.

Power to the showerhead 210 may be provided by a power source 224 that is coupled to the backing plate 202 via a feed line 226. In one embodiment, the power source 224 may comprise an RF power source. In the embodiment shown, the feed line 226 couples to the backing plate 202 at a location corresponding to the substantial center of the backing plate 202. It is to be understood that the power source 224 may couple to the backing plate 202 at other locations as well.

Processing gas may be delivered from a gas source 234 to the processing chamber 200 through the backing plate 202. The gas from the gas source 234 may travel through a remote plasma source 228 prior to reaching the processing chamber 200. In one embodiment, the processing gas passes through the remote plasma source 228 for deposition and thus, does not ignite into a plasma within the remote plasma source 228. In another embodiment, the gas from the gas source 234 may be ignited into a plasma in the remote plasma source 228 and then sent to the processing chamber 200. The plasma from the remote plasma source 228 may clean the processing chamber 200 and the exposed components therein. Additionally, the plasma may clean the cooling block 230 and the choke or resistor 232 through which the gas passes after the remote plasma source 228.

When a plasma is ignited in the remote plasma source 228, the remote plasma source 228 may become very hot. Thus, a cooling block 230 may be disposed between the choke or resistor 232 and the remote plasma source 228 to ensure that the choke or resistor 232 does not crack due to the high temperatures of the remote plasma source 228.

It is to be understood that while two separate gas sources 234 have been shown the remote plasma sources 228 may share a common gas source 234. Additionally, while a remote plasma source 228 is shown coupled between each gas source 234 and the backing plate, the processing chamber 200 may have more or less remote plasma sources 228 coupled to it.

FIG. 2B is a schematic cross-sectional view of the processing chamber 200 of FIG. 2A showing the RF current path. RF current has a “skin effect” whereby the RF current travels on the outside surface of an electrically conductive object and only penetrates into the object to a certain depth. Thus, for a sufficiently thick object, the inside of the object may have zero RF current detectable while the outside surface may have RF current flowing thereon and be considered RF “hot”.

Arrow “A” shows the path that the RF current takes from the power source 224 to the showerhead 210. The RF current travels from the power source 224 along the feed line 226. At location 236, the RF current encounters the backing plate 202 and flows along the back surface of the backing plate 202 and down to the upstream surface 220 of the showerhead 210.

The gas enters the processing chamber 200 through the backing plate 202 at a location 238. Arrow “B” shows the distance between the location 238 where the gas enters the processing chamber 200 and the location 236 where the RF current encounters the backing plate 202. As RF current travels, it may tend to dissipate. In other words, the RF current leaving the power source 224 may have a higher power level as compared to the power level further down the line. In the embodiment shown in FIG. 2B, the RF current at location 236 may have a higher power level as compared to the RF current flowing along the backing plate 202 as it passes location 238 where the gas enters the processing chamber 200. Due to the lower amount of power at location 238 as compared to location 236, the possibility of the gas igniting within the tube 240 containing the gas entering the processing chamber 200 may be reduced. Because of the decreased likelihood of the processing gas igniting in the tube 240, parasitic plasma formation in the tube 238, choke or resistor 232, cooling block 230, remote plasma source 228, and plenum 214 behind the showerhead 210 may be reduced. In one embodiment, the tube 240 may comprise ceramic material.

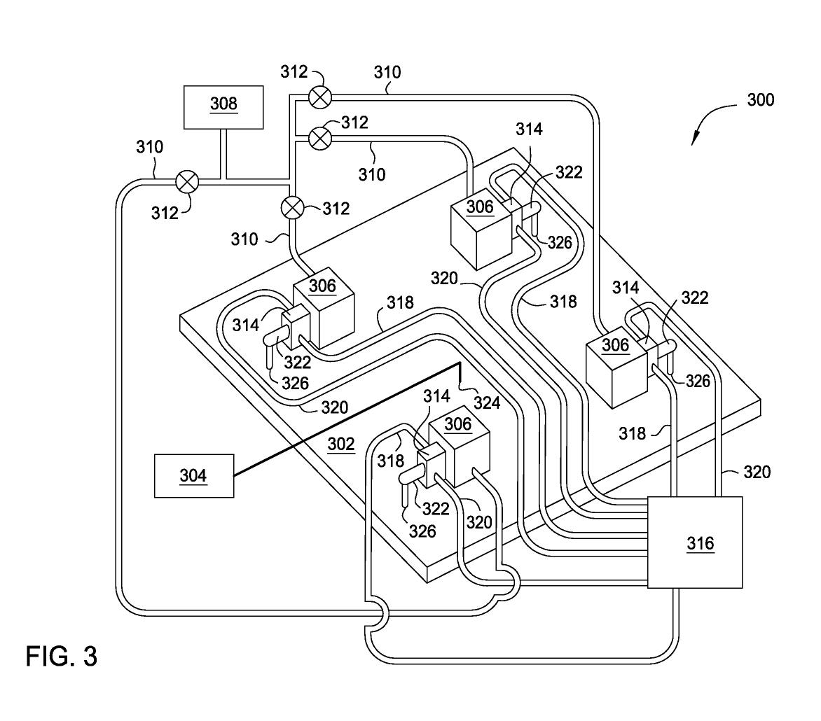

FIG. 3 is a schematic isometric view of a backing plate 302 of a processing chamber 300 according to one embodiment of the invention. RF power may be supplied to the chamber 300 by coupling an RF power source 304 to the backing plate 302 at a location 324. While the location 324 has been shown to correspond to the substantial center of the backing plate 302, it is to be understood that the location 324 may be located at various other points on the backing plate 324. Additionally, more than one location 324 may be simultaneously utilized.

A common gas source 308 may supply the gas to the processing chamber 300. It is to be understood that while a single gas source 308 is shown, multiple gas sources 308 may be utilized. The gas from the gas source 308 may be supplied to the remote plasma sources 306 through gas tubes 310. It is to be understood that while four remote plasma sources 306 are shown, more or less remote plasma sources 306 may be utilized. Additionally, while the remote plasma sources 306 are shown disposed above the backing plate 302, the remote plasma sources 306 may be disposed adjacent the backing plate 302.

The gas from the gas source 308 passes through the gas tubes 310 to the remote plasma sources 306. If the processing chamber 300 is operating in a cleaning mode, the gas in the remote plasma source 306 may be ignited into a plasma and fed to through the cooling block 314 and choke or resistor 322 to the processing chamber 300. However, if the processing chamber is operating in a deposition mode, the gas will pass through the remote plasma source 306 without igniting into a plasma. Without igniting a plasma, the cleaning gas enters the processing chamber in a non-plasma state and may contribute to cleaning inefficiencies.

If one or the remote plasma sources 306 fails or does not run efficiently, the remote plasma source 306 may be shut off. If the other remote plasma sources 306 operate as desired, cleaning gas flowing through the non-functioning remote plasma source 306 into the processing chamber 300 does not ignite prior to entering the processing chamber 300. In such a scenario, the processing chamber 300 cleaning may not proceed as efficiently.

TABLE I

| NF₃ flow rate | RPS units | RPS units | Cleaning |
|---|---|---|---|
| (slm) | working | not working | time (s) |
| 24 | all | none | 24.2 |
| 36 | all | none | 29.5 |
| 48 | all | none | 38 |
| 48 | 3 | 1 | 87.3 |
| 48 | 3 | 1 | 92.2 |
| 48 | 2 | 2 | 248.3 |
| 48 | 2 | 2 | 84.4 |
| 48 | 2 | 2 | 118.9 |

Table I shows the effects of cleaning the chamber whenever one or more remote plasma sources does not work. The chamber is cleaned after SiN deposition. In the data shown in Table I, when the RPS is not working, gas continues to flow through the RPS unit to the chamber. As can be seen from Table I, when one or more RPS units stops functioning, but cleaning gas continues to flow therethrough, the cleaning time increases. However, when the RPS unit fails, but the gas is shut off to the failed RPS unit, cleaning time may not increase.

TABLE II

| NF₃ | | 3 of 4 | | | 3 of 4 | |
|---|---|---|---|---|---|---|
| flow | 1 RPS | RPS | 4 RPS | 1 RPS | RPS | 4 RPS |
| rate | unit | units | units | unit | units | units |
| (slm) | (SiN) | (SiN) | (SiN) | (a-Si) | (a-Si) | (a-Si) |
| 20 | 50.4 | 38.9 | 36.4 | 24.8 | 27.9 | 23.2 |
| 24 | 45.4 | 34.9 | 32.3 | 21.4 | | |
| 27 | 43.0 | 32.6 | 30.6 | 19.9 | 22.6 | 19.0 |
| 36 | | 29.7 | 26.1 | | | |
| 48 | | 22.8 | 22.5 | | 16.8 | 11.4 |

As shown in Table II, by shutting off the gas to a failed RPS unit, the cleaning rate may be substantially maintained. Therefore, it may be beneficial to close a valve 312 in the gas line 310 to prevent cleaning gas from flowing through a non-working remote plasma source 306 and entering the processing chamber 300 without being ignited into a plasma in the remote plasma source 306. Thus, by closing a valve 312, gas flow may be diverted away from a non-working remote plasma source 306. Therefore, the processing chamber 300 may be cleaned utilizing fewer remote plasma sources 306 then are coupled to the backing plate 302. In one embodiment, the valve 312 may be located after the remote plasma source 306.

After passing through a remote plasma source 306, the gas may pass through a cooling block 314. The cooling block 314 may be coupled to a cooling source 316 that flows a cooling fluid to the cooling block 314 through cooling tubes 318. Cooling fluid may flow out of the cooling block 314 and back to the cooling fluid source 316 through a cooling tube 320. The cooling block 314 provides an interface between the remote plasma source 306 and the choke or resistor 322 such that cracking of the choke or resistor 322 is reduced.

After passing through the cooling block 314, the gas passes through a choke or resistor 322. In one embodiment, the choke or resistor 322 may comprise an electrically insulating material such as ceramic. The electrically insulating material may prevent RF power from traveling along the path that the gas flows. The gas may enter the processing chamber 300 through the backing plate 302 at location 326. It is to be understood that while four locations 326 are shown, more or less locations 326 may be utilized for introducing the gas to the processing chamber 300. Additionally, the locations 326 need not be situated near the corners of the backing plate 302. For example, the locations 326 may be situated closer to the center of the backing plate 302.

Additionally, the location 324 where the RF power couples to the backing plate 302 and the locations 326 where the gas enters the processing chamber 300 are not limited to the locations shown. The location 324 may be situated closer to the edge of the backing plate 302 while one or more gas feed locations 326 may be situated in an area corresponding to the center of the backing plate 302.

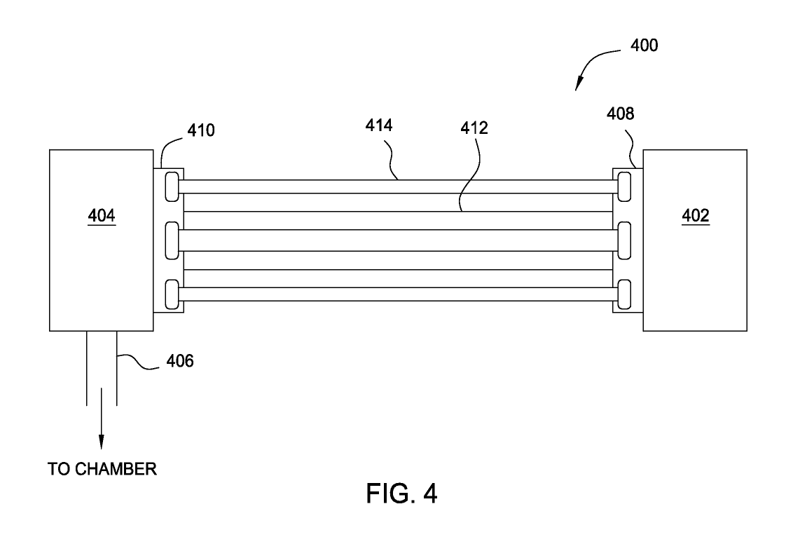

FIG. 4 is a schematic illustration of a coupling between a remote plasma source and the processing chamber according to one embodiment of the invention. A choke or resistor 400 may be coupled between the cooling block 402 and a connection block 404. A resistor 400 is shown in FIG. 4, but it is to be understood that a choke may be used instead. In order to make a choke, a metal coil, such as a copper coil, it wrapped around the outside of the resistor 400. The connection block 404 may be coupled to a tube 406 that permits the gas flowing through the choke or resistor 400 flow into the backing plate. In one embodiment, the tube 406 may comprise ceramic. Additionally, in one embodiment, the connection block 404 may comprise ceramic. In another embodiment, the connection block 404 may comprise stainless steel. In another embodiment, the connection block 404 may comprise aluminum. When the connection block 404 comprises a metal, an electrically insulating material may be used for a tube that connects the tube 412 of the choke or resistor 400 and the tube 406 to the chamber. The cooling block 402 may comprise metal.

The choke or resistor 400 may comprise an inner tube 412 through which gas flows through to reach the chamber. In one embodiment, the inner tube 412 may comprise an electrically insulating material. In another embodiment, the inner tube 412 may comprise ceramic. The inner tube 412 may be present within a casing 414. In one embodiment, the casing 414 may comprise an electrically insulating material. In another embodiment, the casing 414 may comprise ceramic. The electrically insulating material permits the processing gas to flow within the tube without exposing the gas to RF current.

The casing 414 and tube 412 may connect to the connection block 404 at one end 410 and to the cooling block 402 at another end 408. While not shown, electrically conductive material may be wound around the casing 414 in some embodiments. The electrically conductive material may be utilized to provide an additional RF current path to ground if necessary.

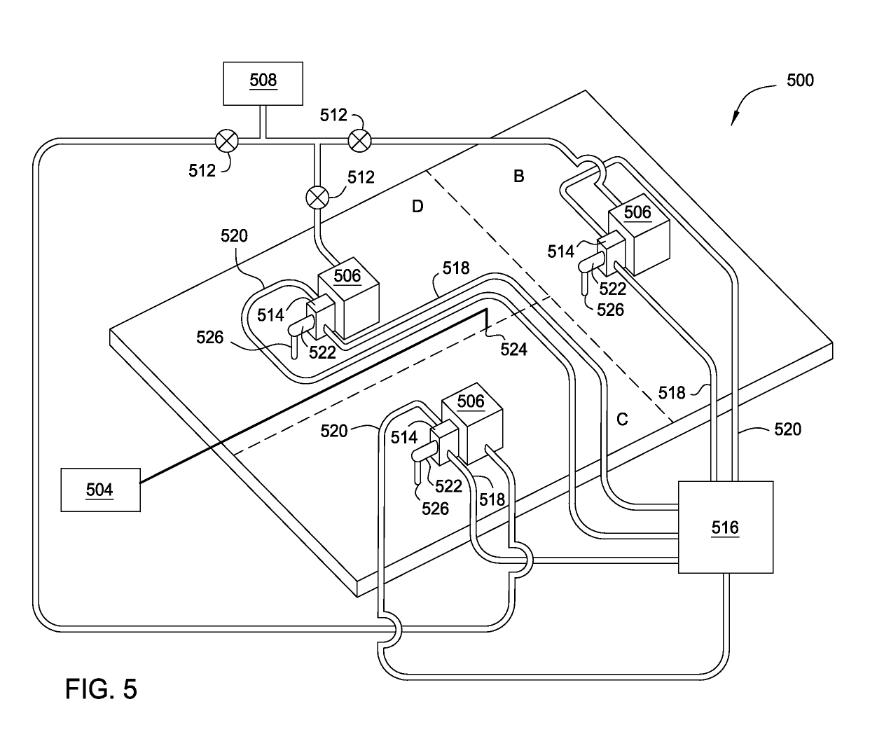

FIG. 5 is a schematic isometric view of a backing plate 502 of a processing chamber 500 according to one embodiment showing three locations for gas feed. The three locations are substantially centered over a substrate that is hypothetically divided into three substantially equal areas. The dashed lines divide the three substantially equal areas. RF power may be supplied to the chamber 500 by coupling an RF power source 504 to the backing plate 502 at a location 524. While the location 524 has been shown to correspond to the substantial center of the backing plate 502, it is to be understood that the location 524 may be located at various other points on the backing plate 524. Additionally, more than one location 524 may be simultaneously utilized.

A common gas source 508 may supply the gas to the processing chamber 500. It is to be understood that while a single gas source 508 is shown, multiple gas sources 508 may be utilized. The gas from the gas source 508 may be supplied to the remote plasma sources 506 through gas tubes 510. While the remote plasma sources 506 are shown disposed above the backing plate 502, the remote plasma sources 506 may be disposed adjacent the backing plate 502.

The gas from the gas source 508 passes through the gas tubes 510 to the remote plasma sources 506. If the processing chamber 500 is operating in a cleaning mode, the gas in the remote plasma source 506 may be ignited into a plasma and the radicals then fed through the cooling block 514 and choke or resistor 522 to the processing chamber 500. However, if the processing chamber is operating in a deposition mode, the gas will pass through the remote plasma source 506 without igniting into a plasma. Without igniting a plasma, the cleaning gas enters the processing chamber in a non-plasma state and may contribute to cleaning inefficiencies.

It may be beneficial to close a valve 512 in the gas line 510 to prevent cleaning gas from flowing through a non-working remote plasma source 506 and entering the processing chamber 500 without being ignited into a plasma in the remote plasma source 506. Thus, by closing a valve 512, gas flow may be diverted away from a non-working remote plasma source 506. Therefore, the processing chamber 500 may be cleaned utilizing fewer remote plasma sources 506 then are coupled to the backing plate 502. In one embodiment, the valve 512 may be located after the remote plasma source 506.

After passing through a remote plasma source 506, the gas may pass through a cooling block 514. The cooling block 514 may be coupled to a cooling source 516 that flows a cooling fluid to the cooling block 514 through cooling tubes 518. Cooling fluid may flow out of the cooling block 514 and back to the cooling fluid source 516 through a cooling tube 520. The cooling block 514 provides an interface between the remote plasma source 506 and the choke or resistor 522 such that cracking of the choke or resistor 522 is reduced.

After passing through the cooling block 514, the gas passes through a choke or resistor 522. In one embodiment, the choke or resistor 522 may comprise an electrically insulating material such as ceramic. The electrically insulating material may prevent RF power from traveling along the path that the gas flows. The gas may enter the processing chamber 500 through the backing plate 502 at location 526.

Additionally, the location 524 where the RF power couples to the backing plate 502 and the locations 526 where the gas enters the processing chamber 500 are not limited to the locations shown. The location 524 may be situated closer to the edge of the backing plate 502 while one or more gas feed locations 526 may be situated in an area corresponding to the center of the backing plate 502.

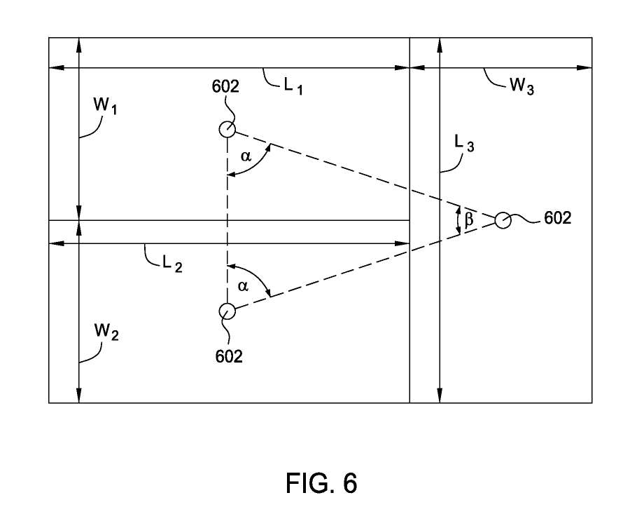

FIG. 6 is a schematic view of a susceptor showing locations of corresponding gas introduction passages. As shown, the susceptor has been divided into three substantially equal areas where the lengths (L1-L3) and the widths (W1-W3) are substantially identical. The center 602 of each area corresponds to the locations above which the gas introductions passages are made through the backing plate. The center 602, and hence, the gas introduction passages, are arranged such that a hypothetical triangle (shown by the dashed lines) has two substantially equals angles (α) and one other angle (β) that may or may not be equal to the other angles (α). Whether angle (β) equals angles (α) will depend upon the layout of the susceptor.

While described as a susceptor, the arrangement could equally apply to the substrate such that the gas passages are centered over three substantially equal areas of a substrate disposed on the susceptor. In another embodiment, the arrangement could equally apply to the backing plate itself such that the gas passages are centered through three substantially equal areas of the backing plate. Additionally, the arrangement could equally apply to a showerhead or electrode such that the gas passages are centered over three substantially equal areas of the showerhead or electrode.

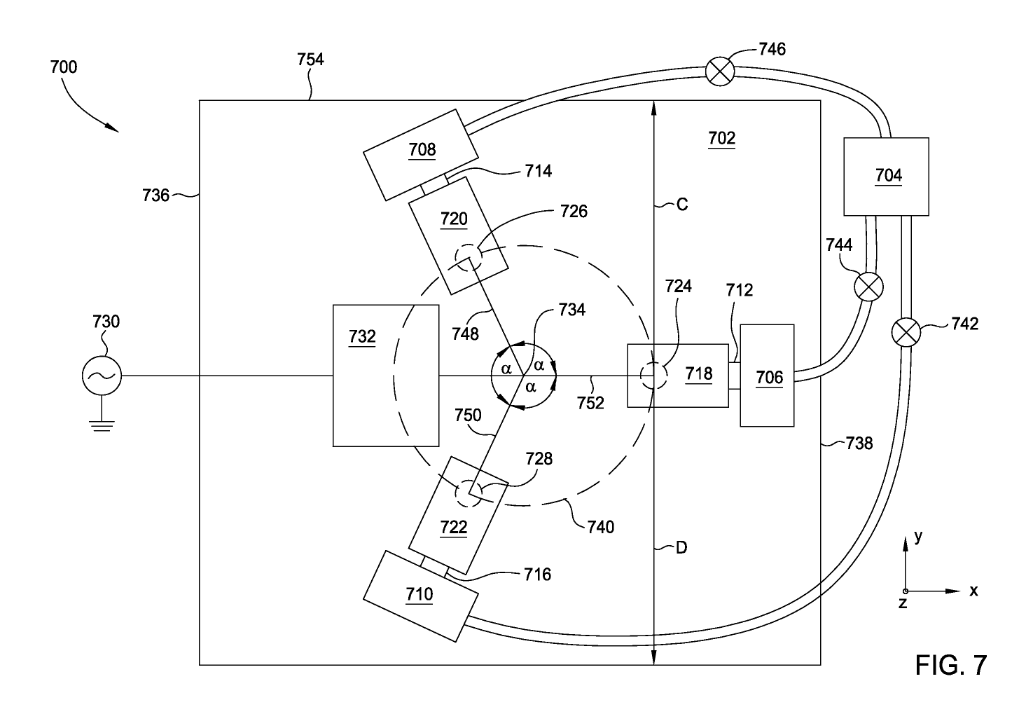

FIG. 7 is a schematic top view of an apparatus 700 according to another embodiment. The apparatus 700 may be a PECVD apparatus. The apparatus 700 includes a backing plate 702. A gas source 704 provides not only processing gas to the processing chamber but also cleaning gas. Although a single gas source 704 is shown, it is to be understood that multiple gas sources may be used.

During deposition, processing gas is fed from the gas source 704 to the processing chamber. The processing gas travels through a remote plasma source 706, 708, 710, a cooling block 712, 714, 716, and a gas feed block 718, 720, 722 before entering the processing chamber through the backing plate 702 at openings 724, 726, 728 (shown in phantom). The cooling blocks 712, 714, 716 are used to provide a connection between the remote plasma sources 706, 708, 710 and the gas feed blocks 718, 720, 722. The remote plasma sources 706, 708, 710 may reach such high temperatures due to the plasma that a temperature gradient between the gas feed blocks 718, 720, 722 and the remote plasma sources 760, 708, 710 may cause either to fail. The cooling blocks 712, 714, 716 may reduce the possibility of system failure.

RF power is provided to the processing chamber from a power source 730 that is coupled to the backing plate 702 through a matching network 732. As shown, the RF power is coupled to the backing plate 702 at the substantial center 734 of the backing plate 702. It is to be understood that the power source 730 may be coupled to the backing plate 702 at other locations as well in addition to or alternative to the center 734 of the backing plate 702. Additionally, the RF power may be delivered at a frequency between about 10 MHz and about 100 MHz. The location where the RF power is delivered is spaced from the location where the gas is delivered.

As shown in FIG. 7, the openings 724, 726, 728 through which the gas enters the processing chamber through the backing plate 702 are spaced from the center 734 of the backing plate 702 such that the gas enters the processing chamber at a location separate from the location where the power source 730 is coupled to the backing plate 702. In the embodiment shown in FIG. 7, the openings 724, 726, 728 are each substantially equally spaced from the center 734 of the backing plate 702. Thus, the openings 724, 726, 728 may be spaced from the center 734 at a common radius 748, 750, 752 as shown by dashed line 740. In one embodiment, the openings 724, 726, 728 may be spaced between about 25 and about 30 inches from the center 734 of the backing plate 702.

By spacing the openings 724, 726, 728 from the RF feed location, the possibility of parasitic plasma igniting near or within the gas feed blocks 718, 720, 722 or the cooling blocks 712, 714, 714 which are located outside of the processing chamber. The RF potential difference is greatest within the chamber at the location where the RF enters the chamber because the RF return path is very close by as the RF current returns along the walls. By having the location where the RF power is coupled to the chamber away from the location where the gas is fed into the chamber, openings 724, 726, 728 are at a location where the RF potential difference is reduced. Hence, the potential for parasitic plasma formation is reduced.

Additionally, the openings 724, 726, 728 may be spaced apart by a predetermined angle α. In one embodiment, the angle α is 120 degrees. A first opening 724 of the three openings 724, 726, 728 is shown to be substantially equally spaced from two sides 754, 756 of the backing plate 702 as shown by arrows C, D. The first opening 724 is spaced from the center 734 and thus is not centered between side 736 and 738. The other two openings 726, 724 are not centered between any of the sides 736, 738, 754, 756.

Because there are three openings 724, 726, 728, it is possible to modulate the processing gas and/or cleaning gas radicals traveling through the backing plate 702 into the processing chamber. For example, valves 742, 744, 746 may be selectively opened and closed to permit processing gas and/or cleaning gas radicals to enter the processing chamber through the openings 724, 726, 728 in a predetermined manner. For example, the processing gas and/or cleaning gas may be selectively delivered through one opening 724, 726, 728 without being delivered through the other openings 724, 726, 728. The opening 724, 726, 728 through which the gas may enter the chamber may be continuously switched in order to, in essence, stir the processing gas and/or cleaning gas radicals within the processing chamber. For processing gases, the plasma ignited within the chamber may be stirred by such a procedure. Similarly, the radicals that may be delivered from the remote plasma sources 706, 708, 710 may be stirred.

The apparatus 700 will have a slit valve opening into the processing chamber to permit a substrate to enter and exit the processing chamber. In the embodiment shown in FIG. 7, side 736 of the apparatus has the slit valve opening. Hence, opening 724 is disposed further away from the slit valve opening than the openings 726, 728.

The slit valve opening in a chamber may affect the plasma distribution within the chamber. The slit valve opening may affect the plasma distribution because the wall that has the slit valve opening is different than the other three walls. The RF current applied to the backing plate 702 seeks to return to its power source 730. In so returning, the RF current travels back to the power source 703 along the walls of the chamber. The RF current traveling back to the power source 730 along the walls affects the plasma due to the difference in RF potential at the wall versus the RF potential of the plasma. Because the wall having the slit valve opening is different than the other walls, the plasma distribution may be affected by the slit valve opening because of the RF potential difference. An uneven plasma distribution can lead to uneven deposition onto a substrate.

The processing gas flow into the chamber may also affect the plasma distribution. The higher the concentration of plasma, the greater the deposition of material may be. It has surprisingly been found that when the processing gas is delivered to the processing chamber through all three openings 724, 726, 728, the amount of deposition that occurs on the center area of the substrate is greater than in other areas. Hence, the deposited material will be ‘center high’. However, when the processing gas is fed into the processing chamber through only one opening 724 and prevented from flowing through the other openings 726, 728, the deposition on the substrate is more uniform. Thus, feeding processing gas through only the one opening 724 and not through openings 726, 728 reduces the ‘center high’ effect.

It is beneficial to feed through opening 724 and not opening 726 or opening 728 because opening 724 is substantially centered between the sides 754, 756 in the “Y” direction, but not in the “X” direction. Openings 726, 728, on the other hand, are not centered in either the “X” or “Y” direction. Because opening 724 is centered between side 754 and side 756, the gas distribution in the “Y” direction is expected to be substantially uniform. Because opening 724 is off center 734 in the “X” direction, the gas distribution may not be uniform in the “X” direction. Thus, opening 724 provides at least one dimension of controllability as opposed to openings 726, 728. The valves 742, 746 may be closed during the deposition to ensure that the processing gas is delivered only through opening 724.

During cleaning of the chamber, on the other hand, the radicals delivered from the plasma generated in the remote plasma sources 706, 708, 710 may enter through all three openings 724, 726, 728 to effectively clean the processing chamber.

In one embodiment, the apparatus 700 may operate as follows. Valves 742 and 746 may be closed to prevent processing gas from entering into the processing chamber through openings 726, 728. Thus, processing gas does not pass through the remote plasma sources 708, 710, the cooling blocks 714, 716, or the gas feed blocks 722, 724. Valve 744 will be opened and processing gas will travel through the remote plasma source 706, the cooling block 712, the gas feed block 718 and through the opening 724 into the processing chamber. The processing gas will travel through the remote plasma source 706 without being ignited into a plasma. By feeding the gas into the processing chamber through only one opening 724, the amount of processing gas is controlled and the potential for center high deposition is reduced. If the gas were fed through all three openings 724, 726, 728, then the deposition may not be uniform and a center high deposition may occur.

RF current will be provided to the processing chamber from the power source 730 delivered through the matching network 732 to the backing plate 702 at a location spaced from the openings 724, 726, 728. The RF current may ignite the processing gas into a plasma to deposit material onto the substrate. After processing, the substrate may be removed and the processing gases evacuated. Thereafter, the processing chamber may be cleaned. The valves 742 and 746 are opened and cleaning gas is delivered from the gas source 704 to the remote plasma sources 706, 708, 710 where it is ignited into a plasma. Radicals from the remote plasma sources 706, 708, 710 may then pass through the cooling blocks 712, 714, 716, the gas feed blocks 718, 720, 722, and through the openings 724, 726, 728 into the processing chamber. The cleaning gas may then etch or remove contaminates from exposed surfaces of the processing chamber.

During cleaning, the amount of cleaning gas is not of great concern. In fact, the more the better to ensure that the chamber is properly cleaned. Therefore, the cleaning gas may be fed through all three openings 724, 726, 728. Uniformity is desired in cleaning, just as in deposition, but when cleaning, the surfaces of the chamber may be relatively inert to the cleaning gas radicals such that mainly material deposited on the chamber surfaces is removed. Very little if any of the chamber is removed. Hence, the more cleaning gas radicals, the better. To ensure as many cleaning radicals are present as possible, all three openings 724, 726, 728 are used. According to the embodiment just discussed, during cleaning, the locations and also the number of feed points is changed for gas entering the chamber. After cleaning, the processing chamber may be evacuated and the processing chamber is ready to be used for deposition again.

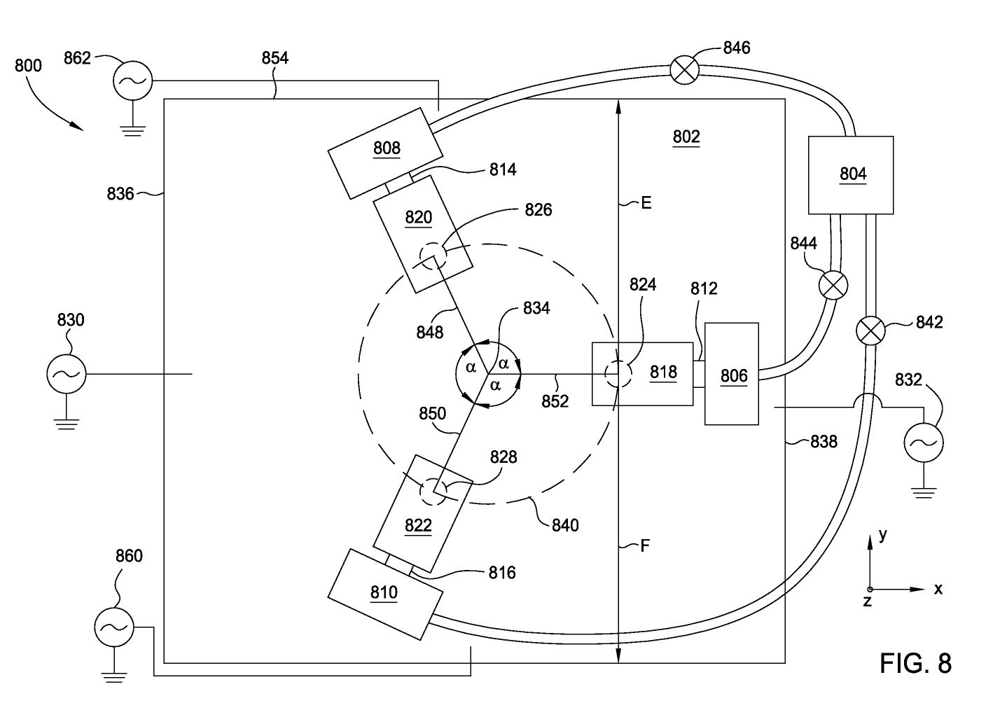

FIG. 8 is a schematic top view of an apparatus 800 according to another embodiment. The apparatus 800 may be a PECVD apparatus. The apparatus 800 includes a backing plate 802. A gas source 804 provides not only processing gas to the processing chamber but also cleaning gas. Although a single gas source 804 is shown, it is to be understood that multiple gas sources may be used.

During deposition, processing gas is fed from the gas source 804 to the processing chamber. The processing gas travels through a remote plasma source 806, 808, 810, a cooling block 812, 814, 816, and a gas feed block 818, 820, 822 before entering the processing chamber through the backing plate 802 at openings 824, 826, 828 (shown in phantom). The cooling blocks 812, 814, 816 are used to provide a connection between the remote plasma sources 806, 808, 810 and the gas feed blocks 818, 820, 822. The remote plasma sources 806, 808, 810 may reach such high temperatures due to the plasma that a temperature gradient between the gas feed blocks 818, 820, 822 and the remote plasma sources 806, 808, 810 may cause either to fail. The cooling blocks 812, 814, 816 may reduce the possibility of system failure.

RF power is provided to the processing chamber from a plurality of power sources 830, 832, 860, 862 that are coupled to the backing plate 802 through matching networks. As shown, the RF power sources 830, 832, 860, 862 are coupled to the backing plate at locations spaced from the substantial center 834 of the backing plate 802. It is to be understood that the power sources 830, 832, 860, 862 may be coupled to the backing plate 802 at other locations as well in including the center 834 of the backing plate 802. Additionally, the RF power may be delivered at a frequency between about 10 MHz and about 100 MHz. The location where the RF power is delivered is spaced from the location where the gas is delivered. Additionally, the phase of the power delivered by the different power sources 830, 832, 860, 862 may be different.

As shown in FIG. 8, the openings 824, 826, 828 through which the gas enters the processing chamber through the backing plate 802 are spaced from the center 834 of the backing plate 802 such that the gas enters the processing chamber at a location separate from the location where the power sources 830, 832, 860, 862 are coupled to the backing plate 802. In the embodiment shown in FIG. 8, the openings 824, 826, 828 are each substantially equally spaced from the center 834 of the backing plate 802. Thus, the openings 824, 826, 828 may be spaced from the center 834 at a common radius 848, 850, 852 as shown by dashed line 840. In one embodiment, the openings 824, 826, 828 may be spaced between about 25 and about 30 inches from the center 834 of the backing plate 802.

By spacing the openings 824, 826, 828 from the RF feed location, the possibility of parasitic plasma igniting near or within the gas feed blocks 818, 820, 822 or the cooling blocks 812, 814, 816 which are located outside of the processing chamber. The RF potential difference is greatest within the chamber at the location where the RF enters the chamber because the RF return path is very close by as the RF current returns along the walls. By having the location where the RF power is coupled to the chamber away from the location where the gas is fed into the chamber, openings 824, 826, 828 are at a location where the RF potential difference is reduced. Hence, the potential for parasitic plasma formation is reduced.

Additionally, the openings 824, 826, 828 may be spaced apart by a predetermined angle α. In one embodiment, the angle α is 120 degrees. A first opening 824 of the three openings 824, 826, 828 is shown to be substantially equally spaced from two sides 854, 856 of the backing plate 802 as shown by arrows E, F. The first opening 824 is spaced from the center 834 and thus is not centered between side 836 and 838. The other two openings 826, 824 are not centered between any of the sides 836, 838, 854, 856.

Because there are three openings 824, 826, 828, it is possible to modulate the processing gas and/or cleaning gas radicals traveling through the backing plate 802 into the processing chamber. For example, valves 842, 844, 846 may be selectively opened and closed to permit processing gas and/or cleaning gas radicals to enter the processing chamber through the openings 824, 826, 828 in a predetermined manner. For example, the processing gas and/or cleaning gas may be selectively delivered through one opening 824, 826, 828 without being delivered through the other openings 824, 826, 828. The opening 824, 826, 828 through which the gas may enter the chamber may be continuously switched in order to, in essence, stir the processing gas and/or cleaning gas radicals within the processing chamber. For processing gases, the plasma ignited within the chamber may be stirred by such a procedure. Similarly, the radicals that may be delivered from the remote plasma sources 806, 808, 810 may be stirred.

The apparatus 800 will have a slit valve opening into the processing chamber to permit a substrate to enter and exit the processing chamber. In the embodiment shown in FIG. 8, side 836 of the apparatus has the slit valve opening. Hence, opening 824 is disposed further away from the slit valve opening than the openings 826, 828.

The slit valve opening in a chamber may affect the plasma distribution within the chamber. The slit valve opening may affect the plasma distribution because the wall that has the slit valve opening is different than the other three walls. The RF current applied to the backing plate 802 seeks to return to its power source 830, 832, 860, 862. In so returning, the RF current travels back to the power source 830, 832, 860, 862 along the walls of the chamber. The RF current traveling back to the power source 830, 832, 860, 860 along the walls affects the plasma due to the difference in RF potential at the wall versus the RF potential of the plasma. Because the wall having the slit valve opening is different than the other walls, the plasma distribution may be affected by the slit valve opening because of the RF potential difference. An uneven plasma distribution can lead to uneven deposition onto a substrate.

The processing gas flow into the chamber may also affect the plasma distribution. The higher the concentration of plasma, the greater the deposition of material may be. It has surprisingly been found that when the processing gas is delivered to the processing chamber through all three openings 824, 826, 828, the amount of deposition that occurs on the center area of the substrate is greater than in other areas. Hence, the deposited material will be ‘center high’. However, when the processing gas is fed into the processing chamber through only one opening 824 and prevented from flowing through the other openings 826, 828, the deposition on the substrate is more uniform. Thus, feeding processing gas through only the one opening 824 and not through openings 826, 828 reduces the ‘center high’ effect.

It is beneficial to feed through opening 824 and not opening 826 or opening 828 because opening 824 is substantially centered between the sides 854, 856 in the “Y” direction, but not in the “X” direction. Openings 826, 828, on the other hand, are not centered in either the “X” or “Y” direction. Because opening 824 is centered between side 854 and side 856, the gas distribution in the “Y” direction is expected to be substantially uniform. Because opening 824 is off center 834 in the “X” direction, the gas distribution may not be uniform in the “X” direction. Thus, opening 824 provides at least one dimension of controllability as opposed to openings 826, 828. The valves 842, 846 may be closed during the deposition to ensure that the processing gas is delivered only through opening 824.

During cleaning of the chamber, on the other hand, the radicals delivered from the plasma generated in the remote plasma sources 806, 808, 810 may enter through all three openings 824, 826, 828 to effectively clean the processing chamber.

In one embodiment, the apparatus 800 may operate as follows. Valves 842 and 846 may be closed to prevent processing gas from entering into the processing chamber through openings 826, 828. Thus, processing gas does not pass through the remote plasma sources 808, 810, the cooling blocks 814, 816, or the gas feed blocks 822, 824. Valve 844 will be opened and processing gas will travel through the remote plasma source 806, the cooling block 812, the gas feed block 818 and through the opening 824 into the processing chamber. The processing gas will travel through the remote plasma source 806 without being ignited into a plasma. By feeding the gas into the processing chamber through only one opening 824, the amount of processing gas is controlled and the potential for center high deposition is reduced. If the gas were fed through all three openings 824, 826, 828, then the deposition may not be uniform and a center high deposition may occur.

RF current will be provided to the processing chamber from the power sources 830, 832, 860, 862 delivered through the matching networks to the backing plate 802 at a location spaced from the openings 824, 826, 828. The RF current may ignite the processing gas into a plasma to deposit material onto the substrate. After processing, the substrate may be removed and the processing gases evacuated. Thereafter, the processing chamber may be cleaned. The valves 842 and 846 are opened and cleaning gas is delivered from the gas source 804 to the remote plasma sources 806, 808, 810 where it is ignited into a plasma. Radicals from the remote plasma sources 806, 808, 810 may then pass through the cooling blocks 812, 814, 816, the gas feed blocks 818, 820, 822, and through the openings 824, 826, 828 into the processing chamber. The cleaning gas may then etch or remove contaminates from exposed surfaces of the processing chamber.

During cleaning, the amount of cleaning gas is not of great concern. In fact, the more the better to ensure that the chamber is properly cleaned. Therefore, the cleaning gas may be fed through all three openings 824, 826, 828. Uniformity is desired in cleaning, just as in deposition, but when cleaning, the surfaces of the chamber may be relatively inert to the cleaning gas radicals such that mainly material deposited on the chamber surfaces is removed. Very little if any of the chamber is removed. Hence, the more cleaning gas radicals, the better. To ensure as many cleaning radicals are present as possible, all three openings 824, 826, 828 are used. According to the embodiment just discussed, during cleaning, the locations and also the number of feed points is changed for gas entering the chamber. After cleaning, the processing chamber may be evacuated and the processing chamber is ready to be used for deposition again.

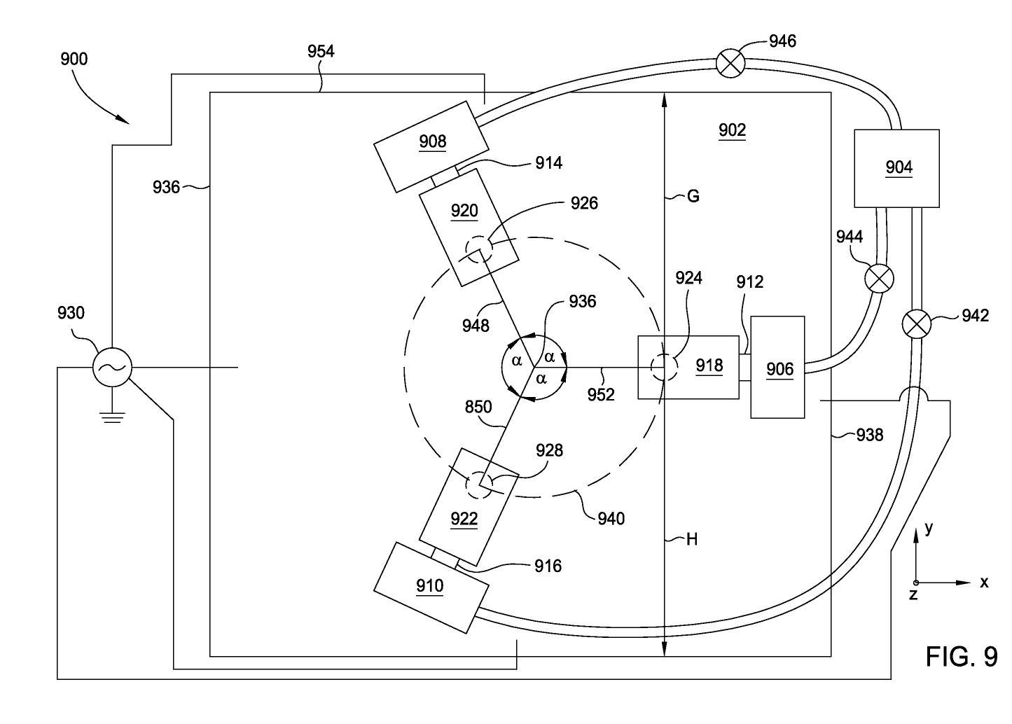

FIG. 9 is a schematic top view of an apparatus 900 according to another embodiment. The apparatus 900 may be a PECVD apparatus. The apparatus 900 includes a backing plate 902. A gas source 904 provides not only processing gas to the processing chamber but also cleaning gas. Although a single gas source 904 is shown, it is to be understood that multiple gas sources may be used.

During deposition, processing gas is fed from the gas source 904 to the processing chamber. The processing gas travels through a remote plasma source 906, 908, 910, a cooling block 912, 914, 916, and a gas feed block 918, 920, 922 before entering the processing chamber through the backing plate 902 at openings 924, 926, 928 (shown in phantom). The cooling blocks 912, 914, 916 are used to provide a connection between the remote plasma sources 906, 908, 910 and the gas feed blocks 918, 920, 922. The remote plasma sources 906, 908, 910 may reach such high temperatures due to the plasma that a temperature gradient between the gas feed blocks 918, 920, 922 and the remote plasma sources 906, 908, 910 may cause either to fail. The cooling blocks 912, 914, 916 may reduce the possibility of system failure.

RF power is provided to the processing chamber from a power source 930 to the backing plate 902 at several locations through matching networks. As shown, the RF power source 930 is coupled to the backing plate 902 at locations spaced from the substantial center 934 of the backing plate 902. It is to be understood that the power source 930 may be coupled to the backing plate 902 at other locations as well, including the center 934 of the backing plate 902. Additionally, the RF power may be delivered at a frequency between about 10 MHz and about 100 MHz. The location where the RF power is delivered is spaced from the location where the gas is delivered.

As shown in FIG. 9, the openings 924, 926, 928 through which the gas enters the processing chamber through the backing plate 902 are spaced from the center 934 of the backing plate 902 such that the gas enters the processing chamber at a location separate from the location where the power source 930 is coupled to the backing plate 902. In the embodiment shown in FIG. 9, the openings 924, 926, 928 are each substantially equally spaced from the center 934 of the backing plate 902. Thus, the openings 924, 926, 928 may be spaced from the center 934 at a common radius 948, 950, 952 as shown by dashed line 940. In one embodiment, the openings 924, 926, 928 may be spaced between about 25 and about 30 inches from the center 934 of the backing plate 902.

By spacing the openings 924, 926, 928 from the RF feed location, the possibility of parasitic plasma igniting near or within the gas feed blocks 918, 920, 922 or the cooling blocks 912, 914, 916 which are located outside of the processing chamber. The RF potential difference is greatest within the chamber at the location where the RF enters the chamber because the RF return path is very close by as the RF current returns along the walls. By having the location where the RF power is coupled to the chamber away from the location where the gas is fed into the chamber, openings 924, 926, 928 are at a location where the RF potential difference is reduced. Hence, the potential for parasitic plasma formation is reduced.

Additionally, the openings 924, 926, 928 may be spaced apart by a predetermined angle α. In one embodiment, the angle α is 120 degrees. A first opening 924 of the three openings 924, 926, 928 is shown to be substantially equally spaced from two sides 954, 956 of the backing plate 902 as shown by arrows G, H. The first opening 924 is spaced from the center 934 and thus is not centered between side 936 and 938. The other two openings 926, 924 are not centered between any of the sides 936, 938, 954, 956.

Because there are three openings 924, 926, 928, it is possible to modulate the processing gas and/or cleaning gas radicals traveling through the backing plate 902 into the processing chamber. For example, valves 942, 944, 946 may be selectively opened and closed to permit processing gas and/or cleaning gas radicals to enter the processing chamber through the openings 924, 926, 928 in a predetermined manner. For example, the processing gas and/or cleaning gas may be selectively delivered through one opening 924, 926, 928 without being delivered through the other openings 924, 926, 928. The opening 924, 926, 928 through which the gas may enter the chamber may be continuously switched in order to, in essence, stir the processing gas and/or cleaning gas radicals within the processing chamber. For processing gases, the plasma ignited within the chamber may be stirred by such a procedure. Similarly, the radicals that may be delivered from the remote plasma sources 906, 908, 910 may be stirred.

The apparatus 900 will have a slit valve opening into the processing chamber to permit a substrate to enter and exit the processing chamber. In the embodiment shown in FIG. 9, side 936 of the apparatus has the slit valve opening. Hence, opening 924 is disposed further away from the slit valve opening than the openings 926, 928.

The slit valve opening in a chamber may affect the plasma distribution within the chamber. The slit valve opening may affect the plasma distribution because the wall that has the slit valve opening is different than the other three walls. The RF current applied to the backing plate 902 seeks to return to its power source 930. In so returning, the RF current travels back to the power source 930 along the walls of the chamber. The RF current traveling back to the power source 930 along the walls affects the plasma due to the difference in RF potential at the wall versus the RF potential of the plasma. Because the wall having the slit valve opening is different than the other walls, the plasma distribution may be affected by the slit valve opening because of the RF potential difference. An uneven plasma distribution can lead to uneven deposition onto a substrate.

The processing gas flow into the chamber may also affect the plasma distribution. The higher the concentration of plasma, the greater the deposition of material may be. It has surprisingly been found that when the processing gas is delivered to the processing chamber through all three openings 924, 926, 928, the amount of deposition that occurs on the center area of the substrate is greater than in other areas. Hence, the deposited material will be ‘center high’. However, when the processing gas is fed into the processing chamber through only one opening 924 and prevented from flowing through the other openings 926, 928, the deposition on the substrate is more uniform. Thus, feeding processing gas through only the one opening 924 and not through openings 926, 928 reduces the ‘center high’ effect.

It is beneficial to feed through opening 924 and not opening 926 or opening 928 because opening 924 is substantially centered between the sides 954, 956 in the “Y” direction, but not in the “X” direction. Openings 926, 928, on the other hand, are not centered in either the “X” or “Y” direction. Because opening 924 is centered between side 954 and side 956, the gas distribution in the “Y” direction is expected to be substantially uniform. Because opening 924 is off center 934 in the “X” direction, the gas distribution may not be uniform in the “X” direction. Thus, opening 924 provides at least one dimension of controllability as opposed to openings 926, 928. The valves 942, 946 may be closed during the deposition to ensure that the processing gas is delivered only through opening 924.

During cleaning of the chamber, on the other hand, the radicals delivered from the plasma generated in the remote plasma sources 906, 908, 910 may enter through all three openings 924, 926, 928 to effectively clean the processing chamber.

In one embodiment, the apparatus 900 may operate as follows. Valves 942 and 946 may be closed to prevent processing gas from entering into the processing chamber through openings 926, 928. Thus, processing gas does not pass through the remote plasma sources 908, 910, the cooling blocks 914, 916, or the gas feed blocks 922, 924. Valve 944 will be opened and processing gas will travel through the remote plasma source 906, the cooling block 912, the gas feed block 918 and through the opening 924 into the processing chamber. The processing gas will travel through the remote plasma source 906 without being ignited into a plasma. By feeding the gas into the processing chamber through only one opening 924, the amount of processing gas is controlled and the potential for center high deposition is reduced. If the gas were fed through all three openings 924, 926, 928, then the deposition may not be uniform and a center high deposition may occur.

RF current will be provided to the processing chamber from the power source 930 delivered through the matching network to the backing plate 902 at locations spaced from the openings 924, 926, 928. The RF current may ignite the processing gas into a plasma to deposit material onto the substrate. After processing, the substrate may be removed and the processing gases evacuated. Thereafter, the processing chamber may be cleaned. The valves 942 and 946 are opened and cleaning gas is delivered from the gas source 904 to the remote plasma sources 906, 908, 910 where it is ignited into a plasma. Radicals from the remote plasma sources 906, 908, 910 may then pass through the cooling blocks 912, 914, 916, the gas feed blocks 918, 920, 922, and through the openings 924, 926, 928 into the processing chamber. The cleaning gas may then etch or remove contaminates from exposed surfaces of the processing chamber.

During cleaning, the amount of cleaning gas is not of great concern. In fact, the more the better to ensure that the chamber is properly cleaned. Therefore, the cleaning gas may be fed through all three openings 924, 926, 928. Uniformity is desired in cleaning, just as in deposition, but when cleaning, the surfaces of the chamber may be relatively inert to the cleaning gas radicals such that mainly material deposited on the chamber surfaces is removed. Very little if any of the chamber is removed. Hence, the more cleaning gas radicals, the better. To ensure as many cleaning radicals are present as possible, all three openings 924, 926, 928 are used. According to the embodiment just discussed, during cleaning, the locations and also the number of feed points is changed for gas entering the chamber. After cleaning, the processing chamber may be evacuated and the processing chamber is ready to be used for deposition again.

By separating the point where the RF current couples of the backing plate from the location where the processing gas couples to the backing plate, parasitic plasma formation within the gas feed to the processing chamber may be reduced.

While the foregoing is directed to embodiments of the present invention, other and further embodiments of the invention may be devised without departing from the basic scope thereof, and the scope thereof is determined by the claims that follow.

1. A plasma processing apparatus, comprising:
a processing chamber having a gas distribution showerhead and a generally rectangularly shaped backing plate;
one or more power sources coupled to the backing plate at one or more first locations; and
one or more gas sources coupled to the backing plate at three other locations that are each separate from the one or more first locations wherein one of the three locations is disposed at a second location substantially equal distance between two parallel sides of the backing plate.

2. The apparatus of claim 1, wherein the apparatus is a plasma enhanced chemical vapor deposition apparatus.

3. The apparatus of claim 1, wherein the one or more power sources comprise a plurality of power sources each coupled to the backing plate at separate locations.

4. The apparatus of claim 1, wherein the three locations are spaced about 120 degrees apart at a substantially equal distance from the first location.

5. The apparatus of claim 1, further comprising one or more remote plasma sources coupled to the at least one gas source.

6. The apparatus of claim 5, wherein the one or more remote plasma sources comprises three remote plasma sources.

7. The apparatus of claim 1, further comprising a slit valve opening through a first wall of the processing chamber.

8. The apparatus of claim 7, wherein the second location is disposed farther from the slit valve opening than the one or more first locations.

9. A plasma enhanced chemical vapor deposition apparatus, comprising:
a processing chamber having a slit valve opening through at least one wall;
a gas distribution showerhead disposed within the processing chamber and spaced from a substrate support;
a backing plate disposed behind the gas distribution showerhead and spaced therefrom, the backing plate having three openings therethrough at three locations, wherein one location of the three locations is disposed farther from the slit valve opening than the other two locations;
one or more gas sources coupled to the backing plate at the three locations; and
one or more RF power source coupled to the backing plate at locations spaced from the three locations.

10. The apparatus of claim 9, wherein the one or more RF power sources comprises one RF power source coupled to the backing plate at a substantial center of the backing plate.

11. The apparatus of claim 10, wherein the three locations are each disposed a substantially equal radial distance from the center of the backing plate.

12. The apparatus of claim 11, wherein the three locations are about 120 degrees apart.

13. The apparatus of claim 9, further comprising a remote plasma source coupled to the backing plate at each of the three locations.

14. A method, sequentially comprising:
introducing processing gas into a chamber through a first location;
igniting the processing gas into a plasma;
depositing material onto a substrate;
introducing cleaning gas into one or more remote plasma source;
igniting the cleaning gas into a plasma in the one or more remote plasma sources; and
flowing radicals from the remotely ignited cleaning gas plasma into the chamber through the first location and at least a second location separate from the first location.

15. The method of claim 14, wherein the chamber has a slit valve opening through a first wall of the chamber, and the second location through which the radicals are flowed is closer to the slit valve opening than the first location.

16. The method of claim 15, wherein the method is a plasma enhanced chemical vapor deposition method.

17. The method of claim 16, wherein the chamber has a backing plate through which the ignited cleaning gas radicals and the processing gas are introduced and wherein the first location is spaced from a substantial center of the backing plate.

18. The method of claim 17, wherein the at least one other location comprises two locations and wherein the two locations and the first location are substantially equally spaced from the substantial center of the backing plate.

19. The method of claim 18, wherein the two locations and the first location are spaced apart by about 120 degrees.

20. The method of claim 14, further comprising applying an RF electrical bias to an electrode in the chamber at a location spaced from the first location.
